(19) United States
(12) Patent Application Publication
(10) Pub. No.: US 2026/0050017 A1
(43) Pub. Date: Feb. 19, 2026

(54) POWER ANALYSIS METHOD AND POWER ANALYSIS SYSTEM

(71) Applicant: INSTITUTE FOR INFORMATION INDUSTRY, TAIPEI (TW)

(72) Inventors: Chia Wei TSAI, Taipei (TW); Li-Syuan CHEN, Taipei (TW); Kuei Chun CHIANG, Taipei (TW); Yung Chieh HUNG, Taipei (TW)

(21) Appl. No.: 18/912,614

(22) Filed: Oct. 11, 2024

(30) Foreign Application Priority Data
Aug. 14, 2024 (TW) 113130475

(51) Int. Cl. G01R 21/133; G01W 1/04

(52) U.S. Cl. CPC G01R 21/133; G01W 1/04

(57) ABSTRACT

A power analysis method, comprising: receiving multiple reference power consumption data; obtaining multiple reference environment data corresponding to the multiple reference power consumption data, wherein the multiple reference power consumption data and the multiple reference environment data are used as multiple reference samples to establish an analysis model; receiving a target power consumption data, and obtaining a target environment data corresponding to the target power consumption data; using the target power consumption data and the target environment data as a target sample to analyze a similarity between the target sample and the multiple reference samples by the analysis model; and calculating an power consumption composition data according to the similarity by the analysis model, wherein the power consumption composition data corresponds to the multiple electrical devices of the plurality of types.

### CROSS-REFERENCE TO RELATED APPLICATION

This application claims priority to Taiwan Application Serial Number 113130475, filed Aug. 14, 2024, which is herein incorporated by reference in its entirety.

### BACKGROUND

### Technical Field

The present disclosure relates to electric power technology, particularly a power analysis method and a power analysis system.

### Description of Related Art

As energy issues receive more and more attention, “energy conservation and carbon reduction” has become the current development goal, hoping to create a sustainable low-carbon society and economy. To achieve energy conservation and carbon reduction, the consumption and composition data of power need to be identified first before further planning and improvement can be made. Therefore, how to design a power analysis technology that can help estimate users'power consumption habits has become a major topic at present.

### SUMMARY

One aspect of the present disclosure is a power analysis method, comprising: receiving a plurality of reference power consumption data, wherein the plurality of reference power consumption data corresponds to a plurality of electrical devices of a plurality of types; obtaining a plurality of reference environment data corresponding to the plurality of reference power consumption data from an external server according to the plurality of reference power consumption data, wherein the plurality of reference power consumption data and the plurality of reference environment data are used as a plurality of reference samples to establish an analysis model; receiving a target power consumption data from an user electricity meter, and obtaining a target environment data corresponding to the target power consumption data from the external server; using the target power consumption data and the target environment data as a target sample to analyze a similarity between the target sample and the plurality of reference samples by the analysis model; and calculating an power consumption composition data according to the similarity by the analysis model, wherein the power consumption composition data corresponds to the plurality of electrical devices of the plurality of types.

Another aspect of the present disclosure is a power analysis system, comprising an user electricity meter and an analysis server. The user electricity meter is configured to obtain a target power consumption data. The analysis server is communicatively connected to the user electricity meter and an external server, so as to receive the target power consumption data from the user electricity meter and obtain a plurality of reference environment data from the external server. The analysis server has an analysis model, the analysis model is trained by a plurality of reference samples formed by a plurality of reference power consumption data and the plurality of reference environment data. Each of the plurality of reference power consumption data corresponds to a plurality of electrical devices of a plurality of types. The analysis server is configured to obtain a target environment data corresponding to the target power consumption data from the external server, so as to use the target power consumption data and the target environment data as a target sample. The analysis server is configured to analyze a similarity between the target sample and the plurality of reference samples by the analysis model to calculate an power consumption composition data, and the power consumption composition data corresponds to the plurality of electrical devices of the plurality of types.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a power analysis system in some embodiments of the present disclosure.

FIG. 2 is a flowchart illustrating a power analysis method in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

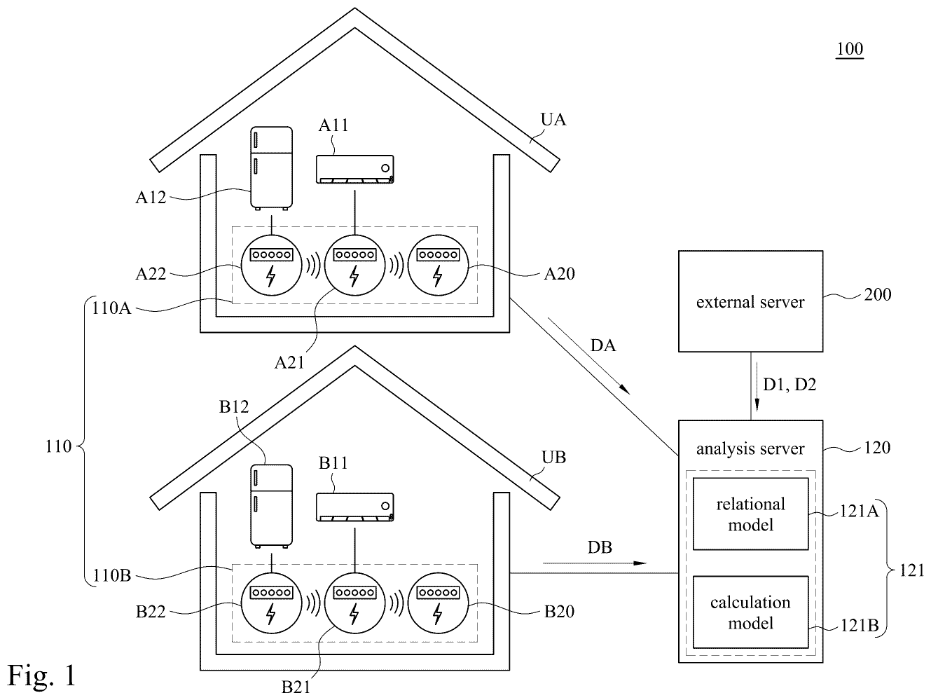

The present disclosure relates to a power analysis method and a power analysis system, which is configured to analyze the electricity usage habit/detail/composition of user according to multiple power consumption data of multiple users, so as to establish an analysis model. The power analysis system is configured to accurately evaluate or estimate the user's power consumption status by the analysis model. FIG. 1 is a schematic diagram of a power analysis system 100 in some embodiments of the present disclosure. The power analysis system 100 includes one or more user electricity meters 110 and an analysis server 120. Each user electricity meter corresponds to different users (e.g., users UA and UB shown in FIG. 1). The analysis server 120 is coupled to the user's electrical device(s) to obtain a power consumption data of the corresponding user.

In the present disclosure, “user” may refer to the same user, household, building or residential area with the same electricity bill. Each user has multiple electrical devices of multiple types, such as electrical devices A11 and B11 (e.g., air conditioners) and electrical devices A12 and B12 (e.g., refrigerators) shown in FIG. 1.

“User electricity meter” may refer to a power detection device used to monitor/detect/record an electricity usage data of the electrical device. For the convenience of subsequent explanation, one or more power detection devices corresponding to the same user are collectively referred to as an “user electricity meter”, as the user electricity meter 110A, 110B shown in FIG. 1. For example, the user electricity meter 110A includes a main meter A20 and multiple submeters A21, A22. The main meter A20 is coupled to a power supply line of the user to obtain all electricity usage data of all electrical devices A11, A1. The submeter A21, A22 is coupled to the different electrical devices A11, A12 to respectively obtain the electricity usage data (e.g., 2 kilowatt-hour (kWh)). However, the present disclosure does not limit the composition of “user electricity meter”. In other embodiments, “user electricity meter” may only include a single submeter, or may not include a main meter.

Similarly, for the convenience of subsequent explanation, one or more electricity usage data corresponding to the same user are collectively referred to as an “power consumption data”. In other words, in some embodiments, “power consumption data” can be subdivided into one or more power consumption records, and each power consumption record corresponds to each electrical device. As shown in FIG. 1, the submeter A21 is configured to detect/record a power consumption record of the electrical device A11, the submeter A22 is configured to detect/record a power consumption record of the electrical device A12. The power consumption records obtained by the main meter A20 and the submeter A21, A22 are classified into the same “power consumption data”.

The analysis server 120 is communicatively connected to the user electricity meters 110, and is configured to receive the power consumption data form the user electricity meters 110. The analysis server 120 has/establishes an analysis model 121, the analysis model 121 is trained by multiple reference samples formed by multiple reference power consumption data and multiple reference environment data. The reference power consumption data and the reference environment data will be detailed in subsequent paragraphs.

The analysis server 120 is further communicatively connected to an external server 200, and is configured to receive an environment data corresponding to the power consumption data from the external server 200. “Environment data” can be a weather data, a temperature data or a humidity data, and the external server 200 can be a third-party information server, such as a weather server, a temperature server or a humidity server. The analysis server 120 trains data by using the power consumption data and the environment data to establish the analysis model 121.

Currently, when analyzing the user's electricity usage, it is necessary to first build a home energy management system, such as using multiple smart meters to record the power consumption data of different electrical devices. However, this approach is limited by construction costs and is therefore difficult to promote. In addition, even if recording the power consumption data of different electrical devices by smart meters, it is still difficult to understand “power consumption habit” of user according to the electricity usage data (power consumption data) alone, so the analysis results are not accurate. The present disclosure receives the power consumption data and the environment data respectively, and uses machine learning or algorithms to establish the analysis model, so it can more accurately estimate the power consumption composition and the electricity consumption details.

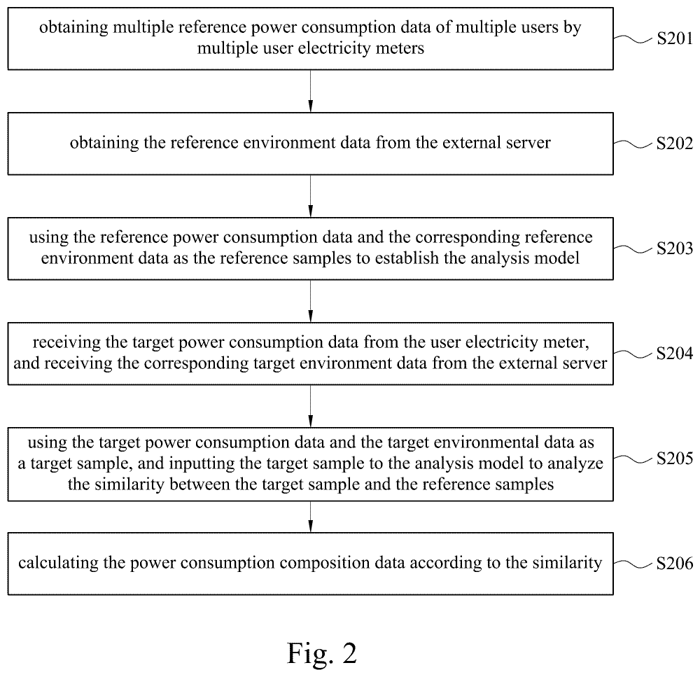

FIG. 2 is a flowchart illustrating a power analysis method in some embodiments of the present disclosure. The power analysis method can be implemented to the power analysis system 100 shown in FIG. 1. Here take FIG. 2 as an example to illustrate the operation of the power analysis system 100, wherein steps S201-S203 are used to “establish the analysis model”, and steps S204-S206 are used to “analyze power consumption composition”.

In step S201, the analysis server 120 receives the power consumption data of user by the user electricity meters 110. As mentioned above, the above “power consumption data” can include detailed and complete electricity usage data, so each power consumption data can correspond to multiple electrical devices of multiple types (categories). For ease of distinction, the power consumption data used to train the analysis model 121 is called “reference power consumption data” here (FIG. 1 only shows one reference power consumption data DA of user), and the reference power consumption data DA includes one or more reference power consumption records, so as to correspond to the electrical devices of multiple types.

In some embodiments, after the analysis server 120 obtains the reference power consumption data DA, the analysis server 120 first “clean” data, that is, filtering the abnormal data (e.g., data that is too large or too small) to prevent the abnormal data from affecting the analysis results.

In step S202, for each of the reference power consumption data DA, the analysis server 120 obtains the corresponding reference environment data D1 from the external server 200, such as current temperature, weather or humidity. As mentioned above, the external server 200 may be a government data open platform or a public database of a third-party provider.

In one embodiment, the reference power consumption data includes the time data of each reference power consumption record. “Time data” can be a recording time of each power detection device. For example, the reference power consumption data DA includes two reference power consumption records “air conditioner, power consumption 2 kWh” and “refrigerator, power consumption 1 kWh”, and the two reference power consumption records respectively have the corresponding time data “1 pm-3 pm” and “May 1st to May 7th”. Therefore, the analysis server 120 can search the reference environment data D1 of the corresponding time according to the time data from the external server 200 (e.g., 1-3 pm, 30 degrees Celsius).

In other embodiments, the reference power consumption data DA further includes a reference region data (e.g., administrative district name, geographical coordinate location) corresponding to the same user. The analysis server 120 searches the reference environment data D1 of the corresponding time from the external server 200 according to the reference region data. For example, when the analysis server 120 receives the reference power consumption data DA, the analysis server 120 obtains the reference environment data D1 of the corresponding region from the external server 200.

As mentioned above, one or more reference power consumption records of the same user are collectively referred to as “reference power consumption data DA”. Therefore, in the present disclosure, “reference environment data D1” is also defined as one or more environment data corresponding to “the reference power consumption records of the same user”. That is, each of the reference power consumption record can correspond to one environment data and correspond to the electrical device.

In step S203, the analysis server 120 integrates each reference power consumption data DA and the corresponding reference environment data D1 into one reference sample (i.e., data corresponding to the same user is used as a sample). In other words, each reference sample comprises one of the reference power consumption data and a corresponding one of the reference environment data. After the establishment number of the reference samples is larger than a training threshold, the analysis server 120 performs training according to the reference samples to establish the analysis model 121. In one embodiment, the analysis model 121 includes one or more training models, and is configured to analyze a similarity between the input new sample and the reference sample, and analyze or estimate the power consumption details that were not previously recorded in the new sample.

Specifically, the analysis model 121 can be subdivided into a relational model 121A and a calculation model 121B. The relational model 121A is configured to analyze a similarity between different samples. In the above step S203, the analysis server 120 compares multiple difference degrees between multiple reference samples, and generates multiple relational parameters according to the difference degrees to establish the relational model 121A.

“Difference degree” refers to the difference between the reference power consumption data and/or the reference environment data of different samples. The analysis server 120 uses “user” as the unit, and uses the corresponding reference power consumption data DA and the reference environment data D1 as a reference sample. The reference sample is integrated into a training vector to train the relational parameters of different features in the relational model 121A.

In one embodiment, the analysis server 120 uses collaborative filtering to analyze a relation between multiple reference samples, so as to generate a relation table between multiple reference samples, and then establishes the relational model 121A. In another embodiment, the analysis server 120 uses regression analysis to analyze the correlation degree and correlation strength (weight value) between multiple reference samples, and then establishes the relational model 121A. Since those skilled in the art can understand the principles of machine learning, they are not further detailed herein.

The calculation model 121B is configured to estimate the power consumption detail missing from the sample according to the difference degree of samples. Specifically, in the above S203, the analysis server 120 generates multiple calculation parameters according to multiple reference power consumption records of each reference power consumption data and the corresponding reference environment data, and then establishes the calculation model 121B.

Steps S204-S206 are used to describe the method of “analyze power consumption composition” as follows: in step S204, when start to analyze power consumption composition, the analysis server 120 receives “the target power consumption data DB” from the user electricity meter (e.g., the user electricity meter 110B). Then, the analysis server 120 receives a target environment data D2 (e.g., weather data, temperature data or humidity data) corresponding to the target power consumption data from the external server 200. Similarly to obtaining the reference environment data, the target power consumption data DB includes a target time data and/or a target region data, so the analysis server 120 can search the corresponding target environment data D2 according to the target time data and/or the target region data from the external server 200.

In step S205, the analysis server 120 uses each target power consumption data DB and the corresponding target environment data D2 as one “target sample”, and inputs the target sample to the analysis model 121, so as to analyze a similarity between the target sample and multiple reference samples by the relational model 121A. In one embodiment, the analysis server 120 uses the relational model 121A and k-Nearest Neighbor Search to search/find k results that are similar to the target sample, and averages the k results as the representative relational sample to be input to the calculation model 121B.

In some embodiments, the number of the relational samples is not limited to one. For example, the relational model 121A can also first analyze a similarity between the target sample and multiple reference samples, and then filters one or more reference samples whose similarity is larger than a filtering threshold. These similar reference samples will be input into the calculation model 121B as “relational sample”.

In step S206, the analysis server 120 calculates the power consumption composition data according to the obtained similarity (relational sample). “Power consumption composition data” may be the electricity usage data that was not previously recorded in the target power consumption data DB (e.g., the power consumption record of the electrical device B12 that cannot be independently detected due to the absence of the submeter B22), and/or the estimated electricity usage data for the future period (e.g., the power consumption of the electrical device B11 in the next week, and is here referred to as “estimated power consumption data”). The power consumption composition data corresponds to the electrical device of one or more types. The analysis server 120 adjusts the corresponding to electrical device according to the power consumption composition data, so as to improve power consumption, such as adjusting the automatic on/off time, or adjusting the preset power or preset status of operation.

Referring to FIG. 1, for example, the analysis server 120 obtains multiple reference power consumption data DA from multiple users (e.g., the user UA), and obtains the corresponding reference environment data D1 from the external server 200 as the reference sample to establish the analysis model 121. The reference sample is the known detailed data used for training, so the reference power consumption data DA includes the power consumption record of each of the electrical devices (e.g., A11, A12).

If a new user (e.g., the user UB) has less complete power detection device, such as not having the submeter B22, and therefore cannot independently detect the power consumption record of the electrical device B12, at this time, the power analysis system 100 can estimate the power consumption record of the electrical device B12 through the above steps S204-S206.

As shown in FIG. 1, after the analysis server 120 establishes the analysis model 121, the analysis server 120 first obtains the target power consumption data DB from the user UB, and obtains the corresponding target environment data D2 from the external server 200. As mentioned above, the target power consumption data DB is not complete, so the target power consumption data DB merely includes power consumption records of the main meter B20 and the submeter B21 (corresponding to the electrical device B11). At this time, the analysis server 120 uses the target power consumption data DB and the target environment data D2 as a target sample, and input the target sample to the relational model 121A, so as to calculate a similarity between the target sample and multiple reference samples. For example, the reference sample of the user UA is most similar to the target sample of the user UB, then the reference sample of the user UA will be used as the relational sample.

As mentioned above, after confirming the similarity and the relational sample, the analysis server 120 inputs the relational sample to the calculation model 121B to calculate the power consumption composition data that the user UB could not detect individually previously, that is, the power consumption record of the electrical device B12. In other words, in one embodiment, “the power consumption composition data” is the power consumption record that has not been recorded by the user, corresponds to the specific type of the electrical device, and corresponds to the recording time of the target power consumption data DB.

In one embodiment, “power consumption composition data” is the consumption record that the analysis model 121 estimates data “has occurred but not be recorded”, but the present disclosure is not limited to this. In some embodiments, “power consumption composition data” is also to be “power consumption status of the user/electrical device for the future period” estimated by the analysis model 121. In other words, “power consumption composition data” is not limited to unrecorded power consumption records, and can includes the estimated power consumption data corresponding to multiple electrical devices of multiple types. As shown in FIG. 1, “power consumption composition data” can be the power consumption record of the electrical devices B11 and B12 for the future period, so that the user UB can understand and evaluate how to improve power consumption.

In addition, in some embodiments, the power analysis system 100 is further configured to regularly determine the accuracy of the estimation of the power consumption composition data to update the analysis model 121. Take the application of “the power consumption composition data is a power consumption record for a future period” as an example, after calculating the power consumption composition data, the analysis server 120 continuously or periodically receives the power consumption data from the user UB (referred to as “power consumption detection data”). The analysis server 120 compares “the actually received power consumption detection data” (including the power consumption record of the electrical device B11) with “the estimated power consumption composition data” (including the power consumption records of the electrical devices B11, B12), so as to obtain an error rate. The error rate is used to represent the calculated accuracy of the analysis model 121.

As mentioned above, if the error rate is larger than a set value, it represents that the calculated accuracy is not as expected. At this time, the analysis server 120 adds the actually recorded power consumption detection data and the target environment data as a new reference sample, and inputs the new reference sample to the relational model 121A of the analysis model 121 to update the database of the relational model 121A.

On the other hand, if the error rate is less than the set value, it represents that the calculated accuracy is as expected, and the relational sample of “the power consumption composition data configured to be calculated/estimated” selected by the analysis server 120 is suitable. At this time, the analysis server 120 find the one or more relational samples used (e.g., one of multiple reference samples that is most similar to the target sample), and updates/adjusts multiple weight values corresponding the relational sample(s) of the relational model 121A in the analysis model 121.

The present disclosure establishes the analysis model according to multiple types of data (power consumption data, environment data), so it can use the relation between the power consumption habit of users and environment data to analyze comprehensively and improve analysis accuracy. Furthermore, by mutually verifying the estimated/calculated results (i.e., the power consumption composition data) and the actual detection result (i.e., the power consumption detection data), the power analysis system 100 can regularly update the analysis model 121 to enhance the diversity of the analysis model 121 and the resilience of the overall application.

The elements, method steps, or technical features in the foregoing embodiments may be combined with each other, and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A power analysis method, comprising:
receiving a plurality of reference power consumption data, wherein the plurality of reference power consumption data corresponds to a plurality of electrical devices of a plurality of types;
obtaining a plurality of reference environment data corresponding to the plurality of reference power consumption data from an external server according to the plurality of reference power consumption data, wherein the plurality of reference power consumption data and the plurality of reference environment data are used as a plurality of reference samples to establish an analysis model;
receiving a target power consumption data from an user electricity meter, and obtaining a target environment data corresponding to the target power consumption data from the external server;
using the target power consumption data and the target environment data as a target sample to analyze a similarity between the target sample and the plurality of reference samples by the analysis model; and
calculating a power consumption composition data according to the similarity by the analysis model, wherein the power consumption composition data corresponds to the plurality of electrical devices of the plurality of types.

2. The power analysis method of claim 1, further comprising:
generating a plurality of relational parameters according to a plurality of difference degrees between the plurality of reference samples to establish a relational model of the analysis model.

3. The power analysis method of claim 2, wherein each of the plurality of reference power consumption data comprises a plurality of reference power consumption records, and the power analysis method comprises:
generating a plurality of calculation parameters according to the plurality of reference power consumption records and the plurality of reference environment data to establish a calculation model of the analysis model.

4. The power analysis method of claim 3, further comprising:
obtaining at least one relational sample in the plurality of reference samples according to the similarity by the relational model; and
inputting the at least one relational sample to the calculation model to calculate the power consumption composition data corresponding to the plurality of electrical devices of the plurality of types.

5. The power analysis method of claim 1, wherein the target environment data comprises a weather data, a temperature data or a humidity data.

6. The power analysis method of claim 5, wherein the target power consumption data comprises a target time data, and obtaining the target environment data corresponding to the target power consumption data from the external server comprises:
obtaining the target environment data from the external server according to the target time data.

7. The power analysis method of claim 5, wherein the target power consumption data comprises a target region data, and obtaining the target environment data corresponding to the target power consumption data from the external server comprises:
obtaining the weather data, the temperature data or the humidity data from the external server according to the target region data.

8. The power analysis method of claim 1, wherein the power consumption composition data comprises a plurality of estimated power consumption data corresponding to the plurality of electrical devices of the plurality of types.

9. The power analysis method of claim 1, further comprising:
receiving a power consumption detection data from the user electricity meter;
comparing the power consumption composition data and the power consumption detection data to obtain an error rate; and
when the error rate is larger than a set value, adding the power consumption detection data and the target environment data as a new reference sample in the analysis model.

10. The power analysis method of claim 1, further comprising:
receiving a power consumption detection data from the user electricity meter;
comparing the power consumption composition data and the power consumption detection data to obtain an error rate; and
when the error rate is less than a set value, finding one of the plurality of reference samples that is most similar to the target sample; and
adjusting a plurality of weight values corresponding to the one of the plurality of reference samples in the analysis model.

11. A power analysis system, comprising:
an user electricity meter configured to obtain a target power consumption data; and
an analysis server communicatively connected to the user electricity meter and an external server, so as to receive the target power consumption data from the user electricity meter and obtain a plurality of reference environment data from the external server, wherein the analysis server has an analysis model, the analysis model is trained by a plurality of reference samples formed by a plurality of reference power consumption data and the plurality of reference environment data, and each of the plurality of reference power consumption data corresponds to a plurality of electrical devices of a plurality of types;
wherein the analysis server is configured to obtain a target environment data corresponding to the target power consumption data from the external server, so as to use the target power consumption data and the target environment data as a target sample;
wherein the analysis server is configured to analyze a similarity between the target sample and the plurality of reference samples by the analysis model to calculate a power consumption composition data, and the power consumption composition data corresponds to the plurality of electrical devices of the plurality of types.

12. The power analysis system of claim 11, wherein each of the plurality of reference samples comprises one of the plurality of reference power consumption data and a corresponding one of the plurality of reference environment data, and the analysis model comprises:
a relational model comprising a plurality of relational parameters, wherein the plurality of relational parameters is generated according to a plurality of difference degrees between the plurality of reference samples, and the analysis server is configured to analyze the similarity between the target sample and the plurality of reference samples by the relational model.

13. The power analysis system of claim 12, wherein each of the plurality of reference power consumption data comprises a plurality of reference power consumption records, the plurality of reference power consumption records corresponds to the plurality of electrical devices, and the analysis model comprises:
a calculation model comprising a plurality of calculation parameters, wherein the plurality of calculation parameters is generated according to the plurality of reference power consumption records and the plurality of reference environment data, and the analysis server is configured to calculate the power consumption composition data by the calculation model.

14. The power analysis system of claim 13, wherein the analysis server is configured to input the target sample to the relational model to analyze the similarity between the target sample and the plurality of reference samples and obtain at least one relational sample in the plurality of reference samples according to the similarity;
wherein the analysis server is further configured to input the at least one relational sample to the calculation model to calculate the power consumption composition data corresponding to the plurality of electrical devices of the plurality of types.

15. The power analysis system of claim 11, wherein the external server is a weather server, a temperature server or a humidity server, and the target environment data comprises a weather data, a temperature data or a humidity data.

16. The power analysis system of claim 15, wherein the target power consumption data comprises a target time data, and the analysis server is configured to obtain the target environment data from the external server according to the target time data.

17. The power analysis system of claim 15, wherein the target power consumption data comprises a target region data, and the analysis server is configured to obtain the weather data, the temperature data or the humidity data from the external server according to the target region data.

18. The power analysis system of claim 11, wherein the power consumption composition data comprises a plurality of estimated power consumption data corresponding to the plurality of electrical devices of the plurality of types.

19. The power analysis system of claim 11, wherein the analysis server is further configured to receive a power consumption detection data from the user electricity meter, when an error rate between the power consumption composition data and the power consumption detection data is larger than a set value, the analysis server is configured to add the power consumption detection data and the target environment data as a new reference sample in the analysis model.

20. The power analysis system of claim 11, wherein the analysis server is further configured to receive a power consumption detection data from the user electricity meter, when an error rate between the power consumption composition data and the power consumption detection data is less than a set value, the analysis server is configured to find one of the plurality of reference samples that is most similar to the target sample, and adjust a plurality of weight values corresponding to the one of the plurality of reference samples in the analysis model.
